(19) United States
(12) Patent Application Publication
(10) Pub. No.: US 2024/0155851 A1
(43) Pub. Date: May 9, 2024

(54) ARRAY SUBSTRATE, METHOD FOR MANUFACTURING ARRAY SUBSTRATE, AND DISPLAY PANEL

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventors: Juncheng Xiao, Guangzhou, Guangdong (CN); Jianwei Fang, Guangzhou, Guangdong (CN); Bin Zhao, Guangzhou, Guangdong (CN)

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/754,991

(22) PCT Filed: Apr. 13, 2022
(86) PCT No.: PCT/CN2022/086551

§ 371 Date: Sep. 28, 2023

(30) Foreign Application Priority Data
Mar. 22, 2022 (CN) 202210284436.2

(51) Int. Cl. H10K 10/43; H10K 19/00; H10K 19/80; H10K 59/125

(52) U.S. Cl. CPC H10K 10/43; H10K 19/202; H10K 19/80; H10K 19/901; H10K 59/125

(57) ABSTRACT

The present invention provides an array substrate, a method for manufacturing the array substrate, and a display panel. The array substrate includes a driving transistor, and the driving transistor includes: a gate electrode; an active layer arranged opposite to a position of the gate electrode, the active layer includes a first semiconductor and second semiconductors, the second semiconductors are in contact with the first semiconductor to form a first PN junction and a second PN junction respectively, and the first PN junction corresponds to the source electrode; and a source drain layer, including a source electrode and a drain electrode. The second semiconductors are electrically connected with the source electrode and drain electrode, respectively.

### FIELD OF INVENTION

The present application relates to a field of display, in particular, to an array substrate, a method for manufacturing the array substrate, and a display panel.

### DESCRIPTION OF PRIOR ART

A thin film transistor (TFT) can be a semiconductor switching device, an on-and-off of an active layer can be controlled by inputting different electrical signals to a gate electrode, so it is widely used in a field of semiconductor display. A thin film driving transistor structure comprises a gate electrode, a gate insulating layer, an active layer, a source drain electrode, and a protective layer. At present, most TFTs are a unipolar N-type semiconductor driver or a P-type semiconductor driver. N-type semiconductor materials mainly comprises amorphous silicon, oxide, and low-temperature polycrystalline silicon, and so on. Metal oxide thin film driving transistors are usually N-type semiconductors, making it difficult to show a P-type performance. Compared with inorganic semiconductor materials, organic semiconductor materials often show better P-type performance and poor N-type performance.

### Technical Problem

The unipolar N-type semiconductor drive or the P-type semiconductor drive has a large power consumption, a complex process, and a high off state leakage current.

### SUMMARY

In view of this, the present invention provides an array substrate and a display panel capable of reducing a power consumption and an off-state leakage current of a driving transistor.

The present invention further provides a method for manufacturing an array substrate which can optimize a manufacturing process of the array substrate.

In order to solve the above problems, a technical scheme provided by the present invention is as follows:

In the first aspect, the present invention provides an array substrate, comprising a substrate and a driving transistor layer arranged on the substrate; wherein the driving transistor layer comprises at least one driving transistor, and the driving transistor comprises:
a gate electrode;
an active layer arranged opposite to a position of the gate electrode, the active layer comprising a first semiconductor and two second semiconductors, the two second semiconductors are arranged at opposite ends of the first semiconductor and are respectively in contact with the first semiconductor to form a first PN junction and a second PN junction, and a conduction direction of the first PN junction and a conduction direction of the second PN junction are inverse; and
a source drain layer arranged opposite to a position of the active layer, the source drain layer comprising a source electrode and a drain electrode, the source electrode is connected with the second semiconductor at a position of the first PN junction, and the drain electrode being connected with the second semiconductor at a position of the second PN junction.

In an optional embodiment of the present invention, the active layer is an NPN type semiconductor, the second semiconductor is an N-type semiconductor layer, and the first semiconductor is a P-type semiconductor layer.

In an optional embodiment of the present invention, the active layer is a PNP type semiconductor, the first semiconductor is an N-type semiconductor layer, and the second semiconductor is a P-type semiconductor layer.

In an optional embodiment of the present invention, a material of the N-type semiconductor layer is an N-type inorganic semiconductor material, and a material of the P-type semiconductor layer is a P-type organic semiconductor material.

In an optional embodiment of the present invention, a material of the N-type semiconductor layer is an N-type inorganic semiconductor material, and a material of the P-type semiconductor layer is a P-type organic semiconductor material.

In an optional embodiment of the present invention, the first semiconductor comprises a channel region, and orthographic projections of two of the second semiconductors on the substrate are located on both sides of an orthographic projection of the channel region on the substrate.

In an optional embodiment of the present invention, the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

In an optional embodiment of the present invention, the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

In an optional embodiment of the present invention, the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

In an optional embodiment of the present invention, the driving transistor layer further comprises a gate insulating layer, a first protective layer, and a second protective layer, the gate insulating layer is arranged on the substrate and covers the gate electrode, the active layer is arranged on the gate insulating layer, the first protective layer covers the active layer and is arranged on the gate insulating layer, and the second protective layer covers the source drain layer.

The second aspect of the present invention provides a method for manufacturing an array substrate, comprising:
providing a substrate;
forming a gate electrode, a gate insulating layer, and a first semiconductor on the substrate; wherein the gate insulating layer covers the gate electrode, and the gate insulating layer is located between the gate electrode and the first semiconductor;
forming a second semiconductor at both opposite ends of the first semiconductor respectively, and forming an active layer by making the two second semiconductors in contact with two ends of the first semiconductor respectively; the first semiconductor layer is one of an N-type semiconductor and a P-type semiconductor, and the second semiconductor layer is other one of the P-type semiconductor and the N-type semiconductor;
forming a source drain layer on the active layer and electrically connecting a source electrode and a drain electrode of the source drain layer with the two second semiconductors respectively.

In an optional embodiment of the present invention, the first semiconductor and/or the second semiconductors is/are formed by evaporation or solution coating method.

The third aspect of the present invention provides a display panel, comprising an array substrate as described above and an opposite substrate, and the array substrate is arranged at a relative interval with the array substrate.

The array substrate and the display panel provided by the present invention. The active layer of the driving transistor in the array substrate comprises a first semiconductor and two second semiconductors. Two of the second semiconductors are arranged at opposite ends of the first semiconductor and are respectively in contact with the first semiconductor. Two of the second semiconductors are electrically connected with the source electrode and the drain electrode respectively, and two of the second semiconductors are respectively in contact with the first semiconductor to form a first PN junction and a second PN junction, and a conduction direction of the first PN junction and a conduction direction of the second PN junction are inverse. The first PN junction corresponds to the source electrode and the second PN junction corresponds to the drain electrode.

When the active layer is an NPN type structure (the first semiconductor is a P-type semiconductor and the second semiconductor is an N-type semiconductor), after a positive voltage is applied to the gate electrode, the first PN junction close to the source electrode is opened. Due to an increasing electron concentration of the first semiconductor (P-type semiconductor), the electrons cross a potential barrier formed by the second PN junction close to the drain electrode and shows a stable on state current. When a negative voltage is applied to the gate electrode, a hole concentration of the first semiconductor (P-type semiconductor) increases, the electron concentration decreases, the first PN junction close to the source electrode is opened, the second PN junction close to the drain electrode has a high potential barrier so that the electrons cannot pass through, there is no current transmission in the channel region, and the source electrode and drain electrode are disconnected. This basically eliminates a leakage current, improves a display effect of the display panel and reduces a power consumption of the driving transistor.

When the active layer is a PNP type structure (the first semiconductor is an N-type semiconductor and the second semiconductor is a P-type semiconductor), after a positive voltage is applied to the gate electrode, the first PN junction close to the source electrode is originally closed. However, after a certain current is applied to the source electrode, the electrons continue to gather to the second semiconductor (P-type semiconductor) corresponding to the source electrode, and the electron concentration continues to rise, and the electrons cross the potential barrier formed by the second PN junction and migrate in the second semiconductor (N-type semiconductor). At this time, the second PN junction is opened to form a stable on state current. A negative voltage is applied to the gate electrode, and a reverse electric field prevents a current applied by the source electrode from entering the second semiconductor (P-type semiconductor). The hole concentration of the second semiconductor (P-type semiconductor) increases, the electron concentration is low. It is more difficult for the electrons to jump over the first PN junction close to the source electrode, there is no current transmission in the channel, and the driving transistor is in the off state. This can reduce a formation of the leakage current and improve the display effect of the display device and reduce the power consumption of the driving transistor.

The array substrate and the display panel provided by the present invention. The active layer of the driving transistor in the array substrate comprises a first semiconductor and two second semiconductors. Two of the second semiconductors are arranged at opposite ends of the first semiconductor and are respectively in contact with the first semiconductor. Two of the second semiconductors are electrically connected with the source electrode and the drain electrode respectively, and two of the second semiconductors are respectively in contact with the first semiconductor to form a first PN junction and a second PN junction, and a conduction direction of the first PN junction and a conduction direction of the second PN junction are inverse. The first PN junction corresponds to the source electrode and the second PN junction corresponds to the drain electrode. When the active layer is an NPN type structure (the first semiconductor is a P-type semiconductor and the second semiconductor is an N-type semiconductor), after a positive voltage is applied to the gate electrode, the first PN junction close to the source electrode is opened. Due to an increasing electron concentration of the first semiconductor (P-type semiconductor), the electrons cross a potential barrier formed by the second PN junction close to the drain electrode and shows a stable on state current. When a negative voltage is applied to the gate electrode, a hole concentration of the first semiconductor (P-type semiconductor) increases, the electron concentration decreases, the first PN junction close to the source electrode is opened, the second PN junction close to the drain electrode has a high potential barrier so that the electrons cannot pass through, there is no current transmission in the channel region, and the source electrode and drain electrode are disconnected. This basically eliminates the leakage current, improves a display effect of the display panel and reduces a power consumption of the driving transistor. When the active layer is a PNP type structure (the first semiconductor is an N-type semiconductor and the second semiconductor is a P-type semiconductor), after a positive voltage is applied to the gate electrode, the first PN junction close to the source electrode is originally closed. However, after a certain current is applied to the source electrode, the electrons continue to gather to the second semiconductor (P-type semiconductor) corresponding to the source electrode, and the electron concentration continues to rise, and the electrons cross the potential barrier formed by the second PN junction and migrate in the second semiconductor. At this time, the second PN junction is opened to form a stable on state current. A negative voltage is applied to the gate electrode, and a reverse electric field prevents a current applied by the source electrode from entering the second semiconductor (P-type semiconductor). The hole concentration of the second semiconductor (P-type semiconductor) increases, the electron concentration is low. It is more difficult for the electrons to jump over the first PN junction close to the source electrode, there is no current transmission in the channel, and the driving transistor is in the off state. This can reduce a formation of the leakage current and improve the display effect of the display device and reduce the power consumption of the driving transistor.

### BRIEF DESCRIPTION OF DRAWINGS

In order to explain the technical solutions in the embodiments of the present application more clearly, the following will briefly introduce the drawings needed in the description of the embodiments. Obviously, the drawings in the following description are only some embodiments of the present application. For those skilled in the art, other drawings can be obtained based on these drawings without creative work.

FIG. 1 is a schematic diagram of a display panel provided by a preferred embodiment of the present invention.

FIG. 2 is a plan view of an array substrate provided by an embodiment of the present invention.

FIG. 3 is a cross-sectional view along a section line shown in FIG. 2.

FIG. 4 is a cross-sectional view of an array substrate provided by another embodiment of the present invention.

FIG. 5 is a cross-sectional view of an array substrate provided by yet another embodiment of the present invention.

FIG. 6 is a flowchart of a method for manufacturing an array substrate provided by a preferred embodiment of the present invention.

### DETAILED DESCRIPTION OF PREFERRED EMBODIMENTS

In the following, the technical scheme in the embodiment of the present application will be described clearly and completely in combination with the drawings. Obviously, the described embodiments are only a part of the embodiments of the present application, rather than all the embodiments. Based on the embodiments of the present application, all other embodiments obtained by those skilled in the art without creative work fall within the protection scope of the present application.

It should be understood that the orientation or position relationship indicated by the terms “up”, “down” and so on is based on the orientation or position relationship shown in the attached drawings, which is only for the convenience of describing the present invention and simplifying the description, rather than indicating or implying that a device or an element must have a specific orientation, be constructed and operated in a specific orientation, so it cannot be understood as a limitation of the present invention.

In the description of this invention, it should be understood that the terms “first” and “second” are only used for descriptive purposes and cannot be understood as indicating or implying relative importance or implicitly indicating the number of indicated technical features. Thus, the features defining “first” and “second” may explicitly or implicitly comprise one or more of the features. In the description of the present invention, “multiple” means two or more, unless otherwise specifically defined.

The present invention can repeat reference numbers and/or reference letters in different embodiments for a purpose of simplification and clarity, which itself does not indicate the relationship between the various embodiments and/or settings discussed.

An array substrate, a method for manufacturing the array substrate, and a display panel provided by the present invention will be described in detail below in combination with specific embodiments and drawings.

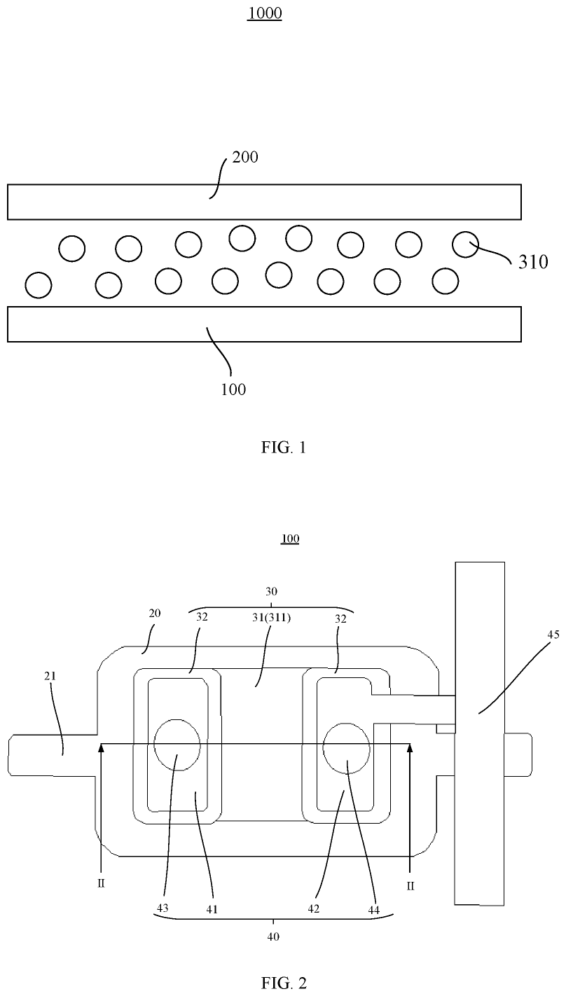

Referring to FIGS. 1-2, the present invention provides a display panel 1000, the display panel 1000 can be a liquid crystal display panel or an OLED display panel, a Micro-LED display panel, a min-LED display panel, an electronic paper, etc. The display panel 1000 comprises an array substrate and an opposite substrate, and the array substrate is arranged at a relative interval with the array substrate. When the display panel 1000 is a liquid crystal display panel and the electronic paper, the opposite substrate is a color film substrate. When the display panel 1000 is the OLED display panel, the Micro-LED display panel, and the min-LED display panel, etc., the opposite substrate can be a cover plate.

Specifically, please refer to FIG. 1. In an optional embodiment of the present invention, the display panel 1000 is the liquid crystal display panel. The display panel 1000 comprises an array substrate 100, liquid crystals 310, and a color film substrate 200. The array substrate 100 is arranged opposite to the color film substrate 200, and the liquid crystals 310 are located between the array substrate 100 and the color film substrate 200. Since the liquid crystals 310 and the color film substrate 200 are well-known structures in the industry, they will not be repeated here. That is, the array substrate 100 can be applied to the liquid crystal display panel.

Specifically, in other embodiments, the display panel 1000 can also be the OLED display panel, the Micro-LED display panel, the min-LED display panel, the electronic paper, etc. The display panel 1000 comprises an array substrate 100, a light-emitting unit (not shown in the figures) and an encapsulation layer (not shown in the figures). The light-emitting unit is formed on the array substrate 100 and electrically connected with the array substrate 100, and the encapsulation layer covers the light-emitting unit. Since the light-emitting unit and the encapsulation layer are well-known structures in the industry, they will not be repeated here. That is, the array substrate 100 can be applied to the OLED display panel, the Micro-LED display panel, the min-LED display panel, the electronic paper, and other display devices.

In an optional embodiment of the present invention, the array substrate 100 can also be applied in a driving of a solar cell and the like.

Specifically, please continue to refer to FIG. 2 to FIG. 6 to illustrate a specific structure of the array substrate 100 provided by the present invention.

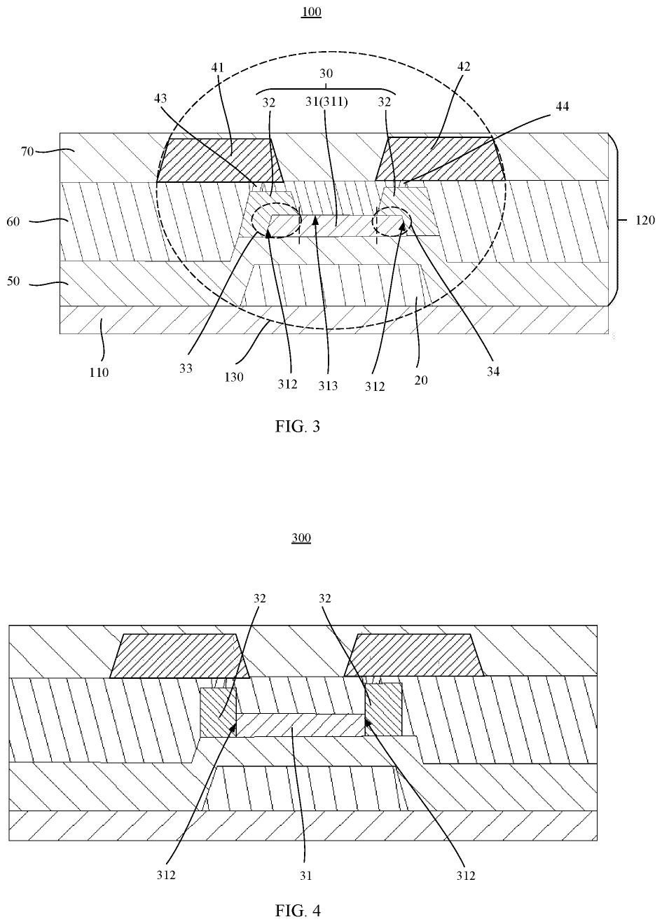

Referring to FIG. 2 and FIG. 3, the array substrate 100 comprises a substrate 110 and a driving transistor layer 120 formed on the substrate 110. The driving transistor layer 120 comprises at least one driving transistor 130, and each of the driving transistors 130 comprises a gate electrode 20, an active layer 30, and a source drain layer 40. The active layer 30 is arranged opposite to a position of the gate electrode 20, and the source drain layer 40 is arranged opposite to a position of the active layer 30. The source drain layer 40 comprises a source electrode 42 and a drain electrode 41.

In an optional embodiment of the present invention, the driving transistor 130 further comprises a first protective layer 60 and a second protective layer 70, the first protective layer 60 covers the active layer 30, and the second protective layer 70 covers the source drain layer 40. The first protective layer 60 is also formed on the gate insulating layer 50.

Wherein the first protective layer 60 is used to protect the active layer 30, and the second protective layer 70 is used to protect the source drain layer 40. Wherein the first protective layer 60 can be an interlayer insulating layer, and the second protective layer can be a passivation layer and/or a planarization layer.

Specifically, referring to FIG. 2, in this embodiment, the driving transistor 130 is a bottom gate structure, the gate electrode 20 is formed on the substrate 110, and the active layer 30 is located on a side of the gate electrode 20 facing away from the substrate 110 and is located between the gate electrode 20 and the source drain layer 40.

In another optional embodiment of the present invention, the driving transistor 130 can also be a top gate structure, the active layer 30 is formed above the substrate 110, and the gate electrode 20 is formed between the active layer 30 and the source drain layer 40 and is located on a side of the second semiconductor 32 of the active layer 30. Specifically, the gate electrode 20 can be formed above the first protective layer 60, and the gate insulating layer 50 can be formed between the gate electrode 20 and the source drain layer 40.

In another optional embodiment of the present invention, the driving transistor 130 can also be a double gate structure, and the driving transistor 130 comprises a first gate electrode and a second gate electrode arranged opposite to each other. In one case, the active layer 30 is formed above the substrate 110, and the first gate electrode and the second gate electrode can be formed between the active layer 30 and the source drain layer 40 and is located on a side of the second semiconductor 32 of the active layer 30. Specifically, the first gate electrode can be located on the side of the second semiconductor 32 of the active layer 30, and the second gate electrode is arranged adjacent to the source drain layer 40. Another case is that a position of the first gate electrode is same as that of the gate electrode 20 in FIG. 2, and the second gate electrode is located between the active layer 30 and the source drain layer 40 and is located on the side of the second semiconductor 32 of the active layer 30.

Wherein the active layer 30 comprises a first semiconductor 31 and two second semiconductors 32. The two second semiconductors 32 are arranged at opposite ends of the first semiconductor 31 and are respectively in contact with the first semiconductor 31, to form a first PN junction 34 and a second PN junction 33. A conduction direction of the first PN junction 34 and a conduction direction of the second PN junction 33 are inverse. Between the two second semiconductors 32 and the first semiconductor 31, the first PN junction 34 corresponds to the source electrode 42, the second PN junction 33 corresponds to the drain electrode 41, the source electrode 42 is connected to the second semiconductor 32 at a position of the first PN junction 34, and the drain electrode 41 is connected to the second semiconductor 32 at a position of the second PN junction 33.

In an optional embodiment of the present invention, the first semiconductor 31 comprises a channel region 311, and orthographic projections of the two second semiconductors 32 on the substrate 110 are located on both sides of an orthographic projection of the channel region 311 on the substrate 110.

The first semiconductor 31 also comprises two end surfaces 312 and a first surface 313, the first surface 313 is connected with the two end surfaces 312, the two end surfaces 312 are respectively located at opposite ends of the first surface 313, and the first surface 313 faces away from the substrate 110.

In an optional embodiment of the present invention, one of the second semiconductors 32 is attached to a corresponding one of the end surfaces 312 and part of the first surface 313.

In an optional embodiment of the present invention, the active layer 30 is an NPN type structure, the second semiconductors 32 are N-type semiconductors, and the first semiconductor 31 is a P-type semiconductor.

In another embodiment of the present invention, the active layer 30 is a PNP type structure, the second semiconductors 32 are P-type semiconductors, and the first semiconductor 31 is an N-type semiconductor.

In an optional embodiment of the present invention, a material of the N-type semiconductor is an N-type inorganic semiconductor material, and a material of the P-type semiconductor layer is a P-type organic semiconductor material.

Wherein the N-type inorganic semiconductor material can be at least one of oxide semiconductor materials such as zinc oxide, zinc tin oxide, titanium oxide, molybdenum oxide, and nickel oxide, and so on, and cadmium selenide, graphene, fullerene, substituted fullerene, etc. In this embodiment, the N-type inorganic semiconductor material is a proportionally mixed semiconductor material such as indium oxide, gallium oxide, and zinc oxide.

The P-type organic semiconductor material is at least one of conjugated aryl compounds, conjugated heteroaryl compounds, etc.

When the active layer is an NPN structure, after a positive voltage is applied to the gate electrode 20, the first PN junction 34 close to the source electrode 42 is opened. Due to an increasing electron concentration of the first semiconductor 31 (P-type semiconductor), the electrons cross a potential barrier formed by the second PN junction 33 close to the drain electrode 41 and shows a stable on-state current. After a negative voltage is applied to the gate electrode 20, a hole concentration of the first semiconductor 31 (P-type semiconductor) increases, the electron concentration decreases, the first PN junction 34 close to the source electrode 42 opens, the second PN junction 33 close to the drain 41 has a high potential barrier causing the electrons to be unable to pass through, there is no current transmission in the channel region 311, and the driving transistor 130 is in an off state. In this way, a leakage current is basically eliminated, and a display effect of the display panel 1000 is improved and a power consumption of the driving transistor 130 is reduced.

When the active layer 30 is a PNP structure, the first PN junction 34 close to the source electrode 42 is originally in a closed state after a positive voltage is applied to the gate electrode 20. However, after a certain current is applied to the source electrode 42, electrons continue to gather toward the second semiconductor 32 (P-type semiconductor) corresponding to the source electrode 42, and the electron concentration continues to rise, and the electrons cross the potential barrier formed by the second PN junction 33 close to the drain electrode 41, and migrate in the second semiconductor 32 (N-type semiconductor), at this time, the second PN junction 33 is opened to form a stable on-state current. A negative voltage is applied to the gate electrode 20, and a reverse electric field prevents the current applied by the source 42 from entering the second semiconductor 32 (P-type semiconductor). The hole concentration of the second semiconductor 32 (P-type semiconductor) increases, the electron concentration is low. It is more difficult for electrons to jump over the first PN junction 34 close to the source electrode 42, there is no current transmission in the channel region 311, and the driving transistor 130 is in the off state. This can reduce formation of the leakage current and improve the display effect of the display panel 1000 and reduce the power consumption of the driving transistor 130.

Wherein the second semiconductors 32 and the first semiconductor 31 of the active layer 30 can be manufactured by a solution processing method. Compared with a particle mixing method or a process of physical vapor deposition or chemical vapor deposition, the manufacturing method is simple, and a manufacturing process of the array substrate can be optimized.

Wherein, when the first semiconductor 31 and/or the second semiconductor 32 is/are (an) N-type semiconductor(s), the first semiconductor 31 or the second semiconductor 32 can be formed by evaporation or solution coating method. When the first semiconductor 31 and/or the second semiconductor 32 is/are (a) P-type semiconductor(s), the first semiconductor 31 or the second semiconductor 32 can be formed by the solution coating method. Wherein the solution coating method refers to making a material for manufacturing the first semiconductor 31 or a material for manufacturing the second semiconductor 32 into a solution, and then coating a prepared solution on the gate insulating layer 50 or the first semiconductor 31 to form the first semiconductor 31 or the second semiconductor 32.

In an optional embodiment of the present invention, the driving transistor 130 is a bottom gate structure. The driving transistor 130 also comprises a gate insulating layer 50. The gate insulating layer 50 is formed on the substrate 110 and covers the gate electrode 20, and the active layer 30 is formed on the gate insulating layer 50. The gate insulating layer 50 is used to insulate the gate electrode 20 and the active layer 30.

The source electrode 42 is electrically connected with one of the second semiconductors 32 through a first via 44. And the drain electrode 41 is electrically connected with another of the second semiconductors 32 through the second via 43.

Wherein the driving transistor 130 further comprises a scanning line 21 and a data line 45. The scanning line 21 extends along a first direction, the data line 45 extends along a second direction, and the first direction is perpendicular to the second direction. The scanning line 21 is connected with the gate electrode 20, and the data line 45 is electrically connected with the source electrode 42.

Referring to FIG. 4, a second embodiment of the present invention further provides an array substrate 300. A structure of the array substrate 300 is similar to a structure of the array substrate 100, except that the two second semiconductors 32 of the array substrate 300 are formed at both ends of the first semiconductor 31 and are in contact with the two end surfaces 312. That is, one of the second semiconductors 32 of the array substrate 300 is only attached to the end surface 312 of the corresponding first surface 313.

In an optional embodiment of the present invention, the second semiconductor 32 protrudes from the first semiconductor 31.

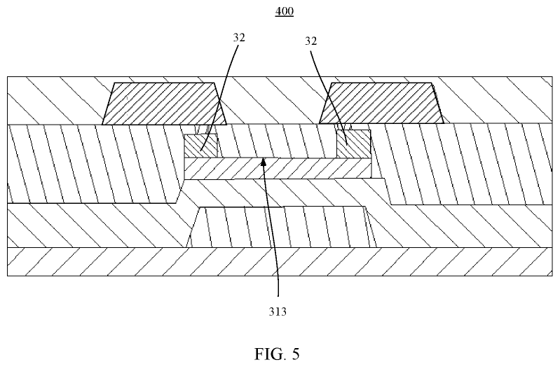

Referring to FIG. 5, a third embodiment of the present invention further provides an array substrate 400. A structure of the array substrate 400 is similar to the structure of the array substrate 100, except that one of the second semiconductors 32 of the array substrate 400 is formed on the first surface 313, that is, one of the second semiconductors 32 of the array substrate 400 is only attached to the first surface 313.

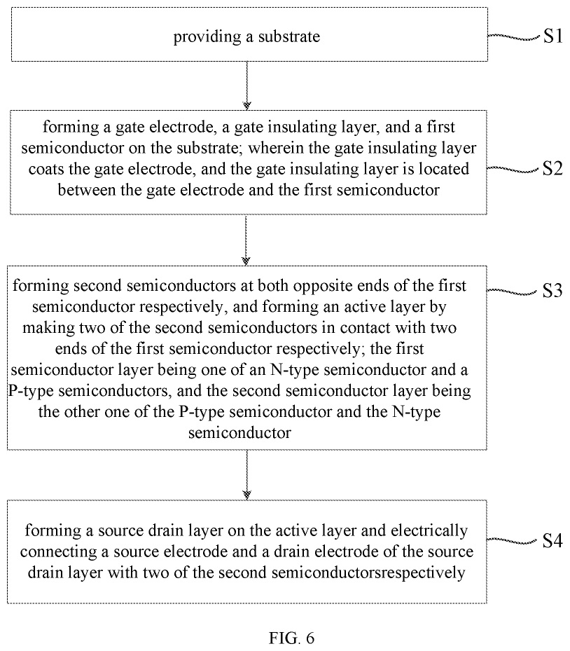

Referring to FIG. 2 and FIG. 6, the present invention further provides a method for manufacturing an array substrate, comprising following steps:
S1: providing a substrate 110; and
S2: forming a gate electrode 20, a gate insulating layer 50, and a first semiconductor 31 on the substrate 110; wherein the gate insulating layer 50 covers the gate electrode 20, and the gate insulating layer 50 is located between the gate electrode 20 and the first semiconductor 31;
S3: forming second semiconductors 32 at both opposite ends of the first semiconductor 31 respectively, and by making two second semiconductors 32 in contact with two ends of the first semiconductor 31 respectively to form an active layer 30. The first semiconductor 31 is one of an N-type semiconductor and a P-type semiconductor, and the second semiconductor 32 is other one of the P-type semiconductor and the N-type semiconductor; and
S4: forming a source drain layer 40 on the active layer 30 and electrically connecting a source electrode 42 and a drain electrode 41 of the source drain layer 40 with the two second semiconductors 32, respectively.

Wherein since the two second semiconductors 32 are respectively in contact with the first semiconductor 31, therefore, a first PN junction 34 and a second PN junction 33 are respectively formed between the two second semiconductors 32 and the first semiconductor 31. The first PN junction 34 corresponds to the source electrode 42, the second PN junction 33 corresponds to the drain electrode 41, and a conduction direction of the first PN junction 34 and a conduction direction of the second PN junction 33 are inverse.

Wherein, when the first semiconductor 31 and/or the second semiconductor 32 is/are (a) N-type semiconductor(s), the first semiconductor 31 or the second semiconductor 32 can be formed by evaporation or solution coating method. When the first semiconductor 31 and/or the second semiconductor 32 is/are (a) P-type semiconductor(s), the first semiconductor 31 or the second semiconductor 32 can be formed by the solution coating method. The solution coating method refers to making a material for manufacturing the first semiconductor 31 or a material for manufacturing the second semiconductor 32 into a solution, and then coating the prepared solution on the gate insulating layer 50 or the first semiconductor 31 to form the first semiconductor 31 or the second semiconductor 32.

Next, a specific step of S3 will be explained by taking the driving transistor 130 as a bottom gate structure as an example.

Specifically, the S3 comprises following steps: first, the gate electrode 20 is formed on the substrate 110. Next, the gate insulating layer 50 covering the gate electrode 20 is formed on the gate electrode 20. Further, the first semiconductor 31 is formed on the gate insulating layer 50 by the solution coating method, and then the second semiconductor layer 32 is formed at both ends of the first semiconductor 31 facing away from the gate insulating layer 50 by the solution coating method to obtain the active layer 30. Then, the first protective layer 60 covering the active layer 30 is formed on the active layer 30, the source drain layer 40 is formed on the first protective layer 60, and the second protective layer 70 is formed on the source drain layer 40.

The present invention provides an array substrate and a display panel, the active layer of the driving transistor in the array substrate comprises a first semiconductor and two second semiconductors. The two second semiconductors are arranged at opposite ends of the first semiconductor and are respectively in contact with the first semiconductor. The two second semiconductors are electrically connected with the source electrode and the drain electrode respectively, and the two second semiconductors are respectively in contact with the first semiconductor to form a first PN junction and a second PN junction, and a conduction direction of the first PN junction and a conduction direction of the second PN junction are inverse. The first PN junction corresponds to the source electrode and the second PN junction corresponds to the drain electrode.

When the active layer is an NPN type structure (the first semiconductor is a P-type semiconductor and the second semiconductor is an N-type semiconductor), after a positive voltage is applied to the gate electrode, the first PN junction close to the source electrode is opened. Due to an increasing electron concentration of the first semiconductor (P-type semiconductor), the electrons cross a potential barrier formed by the second PN junction close to the drain electrode and shows a stable on-state current. When a negative voltage is applied to the gate electrode, a hole concentration of the first semiconductor (P-type semiconductor) increases, the electron concentration decreases, the first PN junction close to the source electrode is opened, the second PN junction close to the drain electrode has a high potential barrier causing the electrons to be unable to pass through, there is no current transmission in the channel region, and the source electrode and drain electrode are disconnected. This basically eliminates a leakage current, improves a display effect of the display panel and reduces a power consumption of the driving transistor.

When the active layer is a PNP type structure (the first semiconductor is an N-type semiconductor and the second semiconductor is a P-type semiconductor), after a positive voltage is applied to the gate electrode, the first PN junction close to the source electrode is originally in a closed state. However, after a certain current is applied to the source electrode, the electrons continue to gather toward the second semiconductor (P-type semiconductor) corresponding to the source electrode, and the electron concentration continues to rise, and the electrons cross the potential barrier formed by the second PN junction and migrate in the second semiconductor (N-type semiconductor). At this time, the second PN junction is opened to form a stable on-state current. A negative voltage is applied to the gate electrode, and a reverse electric field prevents a current applied by the source electrode from entering the second semiconductor (P-type semiconductor). The hole concentration of the second semiconductor (P-type semiconductor) increases, the electron concentration is low. It is more difficult for the electrons to jump over the first PN junction close to the source electrode, there is no current transmission in the channel, and the driving transistor is in an off state. This can reduce a formation of the leakage current and improve the display effect of the display device and reduce the power consumption of the driving transistor.

In addition, the present invention provides a method for manufacturing the array substrate, the second semiconductor and the first semiconductor of the active layer can be prepared by the solution coating method. Compared with the particle mixing method or the process of physical vapor deposition or the chemical vapor deposition, the manufacturing method is simple, the manufacturing process of the array substrate can be optimized, and it is suitable for the manufacture of large-area and flexible devices.

The array substrate, the method for manufacturing the array substrate and the display panel provided by the embodiments of the present invention are introduced in detail. In this paper, specific examples are applied to elaborate the principle and embodiment of the invention. The description of the above embodiment is only used to help understand the technical scheme and core idea of the invention. Those of ordinary skill in the art should understand that they can still modify the technical scheme recorded in the above embodiments, or equivalent replace some of the technical features. These modifications or substitutions do not separate the essence of the corresponding technical scheme from the scope of the technical scheme of each embodiment of the present invention.

What is claimed is:

1. An array substrate, comprising a substrate and a driving transistor layer arranged on the substrate; wherein the driving transistor layer comprises at least one driving transistor, each of the driving transistors comprise:
a gate electrode;
an active layer arranged opposite to a position of the gate electrode, the active layer comprising a first semiconductor and two second semiconductors, the two second semiconductors are arranged at opposite ends of the first semiconductor and are respectively in contact with the first semiconductor to form a first PN junction and a second PN junction, and a conduction direction of the first PN junction and a conduction direction of the second PN junction are inverse; and
a source drain layer arranged opposite to a position of the active layer, the source drain layer comprising a source electrode and a drain electrode, the source electrode is connected with the second semiconductor at a position of the first PN junction, and the drain electrode being connected with the second semiconductor at a position of the second PN junction.

2. The array substrate of claim 1, wherein the active layer is an NPN type semiconductor, the second semiconductor is an N-type semiconductor layer, and the first semiconductor is a P-type semiconductor layer.

3. The array substrate of claim 1, wherein the active layer is a PNP type semiconductor, the first semiconductor is an N-type semiconductor layer, and the second semiconductor is a P-type semiconductor layer.

4. The array substrate of claim 2, wherein a material of the N-type semiconductor layer is an N-type inorganic semiconductor material, and a material of the P-type semiconductor layer is a P-type organic semiconductor material.

5. The array substrate of claim 3, wherein a material of the N-type semiconductor layer is an N-type inorganic semiconductor material, and a material of the P-type semiconductor layer is a P-type organic semiconductor material.

6. The array substrate of claim 1, wherein the first semiconductor comprises a channel region, and orthographic projections of two of the second semiconductors on the substrate are located on both sides of an orthographic projection of the channel region on the substrate.

7. The array substrate of claim 1, wherein the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

8. The array substrate of claim 2, wherein the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

9. The array substrate of claim 3, wherein the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

10. The array substrate of claim 1, wherein the driving transistor layer further comprises a gate insulating layer, a first protective layer, and a second protective layer, the gate insulating layer is arranged on the substrate and covers the gate electrode, the active layer is arranged on the gate insulating layer, the first protective layer covers the active layer and is arranged on the gate insulating layer, and the second protective layer covers the source drain layer.

11. A method for manufacturing an array substrate, wherein the method comprises:
providing a substrate;
forming a gate electrode, a gate insulating layer, and a first semiconductor on the substrate; wherein the gate insulating layer covers the gate electrode, and the gate insulating layer is located between the gate electrode and the first semiconductor;
forming a second semiconductor at both opposite ends of the first semiconductor respectively, and forming an active layer by making the two second semiconductors in contact with two ends of the first semiconductor respectively; the first semiconductor layer is one of an N-type semiconductor and a P-type semiconductor, and the second semiconductor layer is other one of the P-type semiconductor and the N-type semiconductor;
forming a source drain layer on the active layer and electrically connecting a source electrode and a drain electrode of the source drain layer with the two second semiconductors respectively.

12. The method for manufacturing the array substrate of claim 11, wherein the first semiconductor and/or the second semiconductors is/are formed by evaporation or solution coating method.

13. A display panel, wherein the display panel comprises an array substrate and an opposite substrate, and the array substrate is arranged at an interval relative with the opposite substrate; the array substrate comprises a substrate and a driving transistor layer formed on the substrate; wherein the driving transistor layer comprises at least one driving transistor, each of the driving transistors comprise:
a gate electrode;
an active layer arranged opposite to a position of the gate electrode, the active layer comprising a first semiconductor and two second semiconductors, the two second semiconductors are arranged at opposite ends of the first semiconductor and are respectively in contact with the first semiconductor to form a first PN junction and a second PN junction, and a conduction direction of the first PN junction and a conduction direction of the second PN junction are inverse; and
a source drain layer arranged opposite to a position of the active layer, the source drain layer comprising a source electrode and a drain electrode, the source electrode is connected with the second semiconductor at a position of the first PN junction, and the drain electrode being connected with the second semiconductor at a position of the second PN junction.

14. The display panel of claim 13, wherein the active layer is an NPN type semiconductor, the second semiconductor is an N-type semiconductor layer, and the first semiconductor is a P-type semiconductor layer.

15. The display panel of claim 13, wherein the active layer is a PNP type semiconductor, the first semiconductor is an N-type semiconductor layer, and the second semiconductor is a P-type semiconductor layer.

16. The display panel of claim 14, wherein a material of the N-type semiconductor layer is an N-type inorganic semiconductor material, and a material of the P-type semiconductor layer is a P-type organic semiconductor material.

17. The display panel of claim 15, wherein a material of the N-type semiconductor layer is an N-type inorganic semiconductor material, and a material of the P-type semiconductor layer is a P-type organic semiconductor material.

18. The display panel of claim 13, wherein the first semiconductor comprises a channel region, and orthographic projections of two of the second semiconductors on the substrate are located on both sides of an orthographic projection of the channel region on the substrate.

19. The display panel of claim 13, wherein the first semiconductor comprises two end surfaces and a first surface connected with the two end surfaces, the first surface is facing away from the substrate, the two end surfaces are respectively located at opposite ends of the first surface, and one of the second semiconductors is attached to a corresponding one of the end surfaces and/or the first surface.

20. The display panel of claim 13, wherein the driving transistor layer further comprises a gate insulating layer, a first protective layer, and a second protective layer, the gate insulating layer is arranged on the substrate and covers the gate electrode, the active layer is arranged on the gate insulating layer, the first protective layer covers the active layer and is arranged on the gate insulating layer, and the second protective layer covers the source drain layer.
